(19) United States
(12) Patent Application Publication
(10) Pub. No.: US 2016/0126282 A1
(43) Pub. Date: May 5, 2016

(54) CMOS IMAGE SENSOR WITH ENHANCED DYNAMIC RANGE

(71) Applicant: Powerchip Technology Corporation, Hsinchu (TW)

(72) Inventors: Min-Hui Chen, Hsinchu County (TW); Chih-Ping Chung, Hsinchu City (TW); Ming-Yu Ho, Taichung City (TW)

(21) Appl. No.: 14/552,501

(22) Filed: Nov. 25, 2014

(30) Foreign Application Priority Data
Oct. 31, 2014 (TW) 103137902

(51) Int. Cl. H01L 27/146

(52) U.S. Cl. CPC H01L 27/14643; H01L 27/14609; H01L 27/1461; H01L 27/14612; H01L 27/1463; H01L 27/14636

(57) ABSTRACT

An image sensor includes a semiconductor substrate having a main surface, a transfer transistor having a transfer gate disposed on the main surface, a light-sensing structure on one side of the transfer gate, a floating diffusion node on the other side of the transfer gate, a reset transistor serially connected to the transfer transistor via the floating diffusion node, a source-follower transistor having a source-follower gate, and a vertical capacitor having a first vertical electrode plate and a second vertical electrode plate. The first vertical electrode plate is electrically connected to the source-follower gate and the floating diffusion node.

### CROSS REFERENCE TO RELATED APPLICATION

This application claims the benefit of Taiwan patent application No. 103137902, filed on Oct. 31, 2014, the disclosure of which is incorporated herein in its entirety by reference.

### BACKGROUND OF THE INVENTION

1. Field of the Invention

The present invention relates generally to an image sensor device and, more particularly, to a CMOS image sensor device with enhanced dynamic range.

2. Description of the Prior Art

CMOS image sensors are known in the art. A CMOS image sensor may have active components, such as transistors, which are associated with each pixel. Because of the compatibility with the CMOS process, an advantage is the ability to integrate signal processing circuit and sensing circuit within a single chip.

The CMOS image sensor is typically composed of four transistors and a “pinned” photodiode. It is known that the “pinned” photodiode provides improved dark current density and image lag, and has high color response to blue light. The surface potential of the diode is pinned through a P⁺ region to a P well or a P substrate (ground) to reduce the dark current.

It is also known that the pixel dynamic range of a CMOS image sensor is associated with the charge handling capacitance (C_{FD}) of its floating diffusion node. Typically, C_{FD} is less than the charge handling capacitance (C_{PD}) of the photodiode. Therefore, it is difficult to completely transfer the charge from the photodiode to the floating diffusion node when the pixel is under high-brightness exposure. When the channel of a transfer transistor is turned off, the charge remaining in the photodiode results in image lag, and it also affects the pixel dynamic range.

Therefore, a need remains in the art for an improved CMOS image sensor, which can solve the above-mentioned deficiencies and disadvantages of the prior art.

### SUMMARY OF THE INVENTION

According to the embodiment of the invention, an image sensor includes a semiconductor substrate having a main surface, a transfer transistor having a transfer gate disposed on the main surface, a light-sensing structure on one side of the transfer gate, a floating diffusion node on the other side of the transfer gate, a reset transistor serially connected to the transfer transistor via the floating diffusion node, a source-follower transistor having a source-follower gate, and a vertical capacitor having a first vertical electrode plate and a second vertical electrode plate. The first vertical electrode plate is electrically connected to the source-follower gate and the floating diffusion node.

According to the embodiment of the invention, the source-follower gate is electrically coupled to the floating diffusion node through a first conductive plug, a first metal interconnection, and a second conductive plug. The first conductive plug and the second conductive plug are disposed in the same dielectric layer. The source-follower gate is electrically coupled to the first vertical electrode plate of the vertical capacitor structure through a second metal interconnection.

According to the embodiment of the invention, the first vertical electrode plate and the second vertical electrode plate are interdigitated. The first vertical electrode plate and the second vertical electrode plate are disposed vertical to the main surface of the semiconductor substrate.

According to the embodiment of the invention, the transfer transistor and the reset transistor are disposed on a first active region, and the source-follower transistor and the readout transistor are disposed on a second active region, wherein the first active region is isolated from the second active region by a shallow trench isolation (STI) structure.

According to the embodiment of the invention, the light-sensing structure is a photodiode comprising a P⁺ surface doping region and an N⁻ doping region, which constitute a pinned photodiode in the semiconductor substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram showing an exemplary layout of a CMOS image sensor according to the one embodiment of the present invention

FIG. 2 is a cross-sectional diagram taken along line I-I′ in FIG. 1.

FIG. 3 and FIG. 4 are perspective diagrams showing the exemplary capacitor structure.

FIG. 5 and FIG. 6 are schematic cross-sectional diagrams showing CMOS image sensors according to other embodiments of the present invention.

FIG. 7 illustrates another embodiment of the invention.

### DETAILED DESCRIPTION

In the following detailed description of the invention, reference is made to the accompanying drawings, which form a part hereof, and in which is shown, by way of illustration, specific embodiments in which the invention may be practiced. These embodiments are described in sufficient detail to enable those skilled in the art to practice the invention. Other embodiments may be utilized and structural, logical, and electrical changes may be made without departing from the scope of the present invention. The following detailed description is, therefore, not to be taken in a limiting sense, and the scope of the present invention is defined by the appended claims.

The term “horizontal” as used herein is defined as a plane parallel to the conventional major plane or main surface of the semiconductor substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “over”, and “under”, are defined with respect to the horizontal plane.

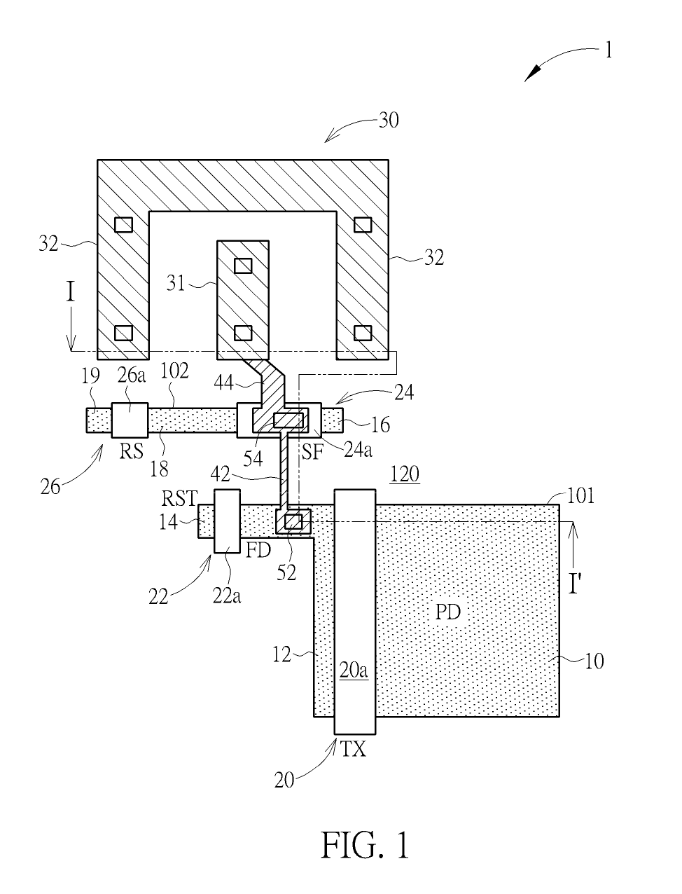

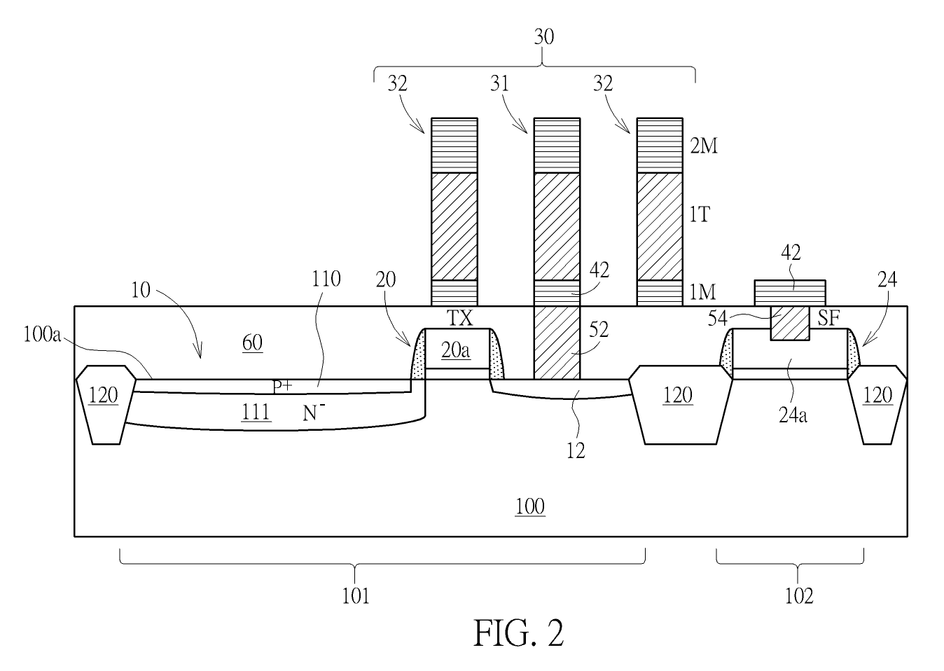

Please refer to FIG. 1 and FIG. 2. FIG. 1 is a schematic diagram showing an exemplary layout of a CMOS image sensor according to the one embodiment of the present invention. FIG. 2 is a cross-sectional diagram taken along line I-I′ in FIG. 1. It should be understood by those skilled in the art that the layout structures shown in the figures are only illustrative and the invention is not limited to these arrangements. As shown in FIG. 1 and FIG. 2, the CMOS image sensor 1 may be a four-transistor (4T) pixel structure, which comprises a transfer transistor (TX) 20, a reset transistor (RST) 22, a source-follower transistor (SF) 24, and a readout transistor (RS) 26. The transfer transistor (TX) 20 is coupled to a photodiode 10.

As shown in FIG. 2, according to the embodiment of the invention, the photodiode 10 may include, but not limited to, a P⁺ surface doping region 110 and an N⁻ doping region 111, which constitute a pinned photodiode in the semiconductor substrate 100. It is to be understood that the photodiode 10 may be other photo-sensing structures. The photodiode 10 is disposed on one side of the transfer gate 20a in the semiconductor substrate 100. According to the embodiment of the invention, the semiconductor substrate 100 may be a P type silicon substrate, but not limited thereto.

According to the embodiment of the invention, as shown in FIG. 1 and FIG. 2, on the other side of the transfer gate 20a opposite to the aforesaid photodiode 10, a commonly-used floating diffusion node (FD) 12 is disposed between a transfer transistor (TX) 20 and a reset transistor (RST) 22. Through the floating diffusion node (FD) 12, the transfer transistor (TX) 20 is serially connected to the reset transistor (RST) 22. On one side of the reset gate 22a opposite to the floating diffusion node (FD) 12, a doping region 14 is disposed.

According to the embodiment of the invention, as shown in FIG. 1 and FIG. 2, the transfer transistor (TX) 20 and the reset transistor (RST) 22 are disposed on a first active region 101, and the source-follower transistor (SF) 24 and the readout transistor (RS) 26 are disposed on a second active region 102. According to the embodiment of the invention, the first active region 101 is isolated from the second active region 102 by a shallow trench isolation (STI) structure 120.

According to the embodiment of the invention, the stripe-shaped second active region 102 is disposed along one side of the first active region 101 and is parallel with the stripe-shaped first active region 101, such that the source-follower transistor (SF) 24 is in close proximity to the floating diffusion node (FD) 12. It is to be understood by those skilled in the art that the layout shown in the figure is for illustration purposes only, and the invention is not limited to the illustrated layout.

According to the embodiment of the invention, as shown in FIG. 1 and FIG. 2, the source-follower transistor (SF) 24 may comprise a source-follower gate 24a, a doping region 16, and a common doping region 18. The readout transistor (RS) 26 may comprise a readout gate 26a, the common doping region 18, and a doping region 19.

According to the embodiment of the invention, in operation, a V_{DD1} voltage may be applied to the doping region 16 of the source-follower transistor (SF) 24, a V_{DD2} voltage may be applied to the doping region 14 of the reset transistor (RST) 22, a V_{TX} (transfer gate voltage) may be applied to the transfer gate 20a, a V_{RST} (reset gate voltage) may be applied to the reset gate 22a, and a V_{RS} (readout gate voltage) may be applied to the readout gate 26a.

According to the embodiment of the invention, as shown in FIG. 1 and FIG. 2, it is one technical feature of the invention that the source-follower gate 24a is electrically coupled to the floating diffusion node (FD) 12 through a first conductive plug 52, a first metal interconnection 42, and a second conductive plug 54. The first conductive plug 52 electrically connects the floating diffusion node (FD) 12 to the first metal interconnection 42. The second conductive plug 54 electrically connects the source-follower gate 24a to the first metal interconnection 42.

As shown in FIG. 2, the first conductive plug 52 and the second conductive plug 54 are formed in a dielectric layer 60. The first conductive plug 52 and the second conductive plug 54 may comprise tungsten, but not limited thereto. The first interconnection 42 may be the first level metal (1M) fabricated in the back-end-of-line (BEOL) process.

According to the embodiment of the invention, as shown in FIG. 1 and FIG. 2, it is another technical feature that the source-follower gate 24a is further electrically coupled to a capacitor structure 30 through a second metal interconnection 44. More specifically, the source-follower gate 24a is electrically coupled to a first electrode plate 31 of the capacitor structure 30 through the second metal interconnection 44. The second interconnection 44 and the first interconnection 42 are both formed in the first level metal (1M). The capacitor structure 30 further comprises a second electrode plate 32 spaced apart from the first electrode plate 31. According to the embodiment of the invention, as shown in FIG. 1, the first electrode plate 31 and the second electrode plate 32 may be interdigitated.

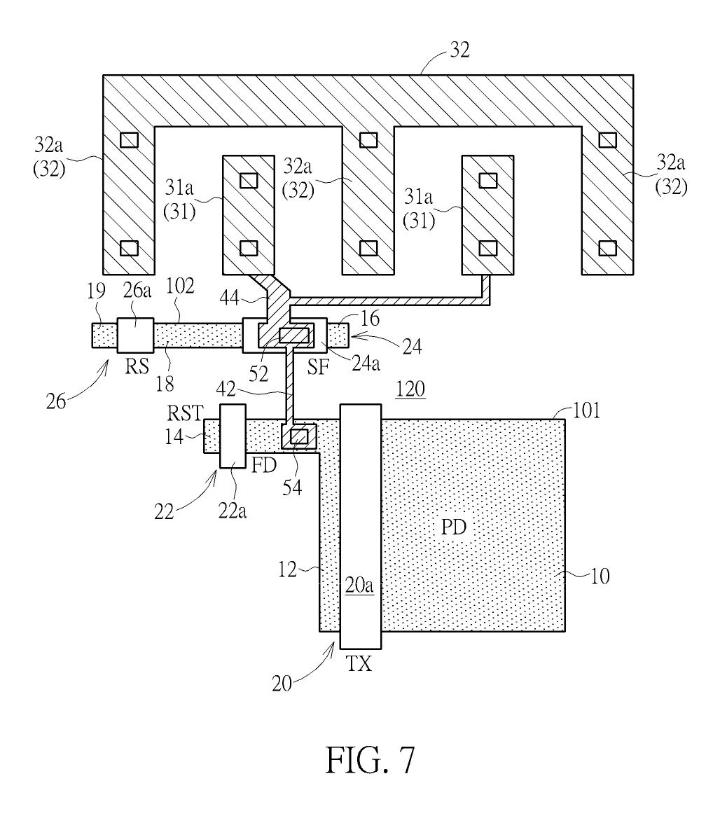

FIG. 7 illustrates another embodiment of the invention. The first electrode plate 31 may have at least two finger electrode plates 31a, which are both electrically coupled to the metal interconnection 44. The second electrode plate may have at least three finger electrode plates 32a. It is to be understood by those skilled in the art that the capacitor structure shown in the figure is for illustration purposes only, and the invention is not limited to the illustrated capacitor structure.

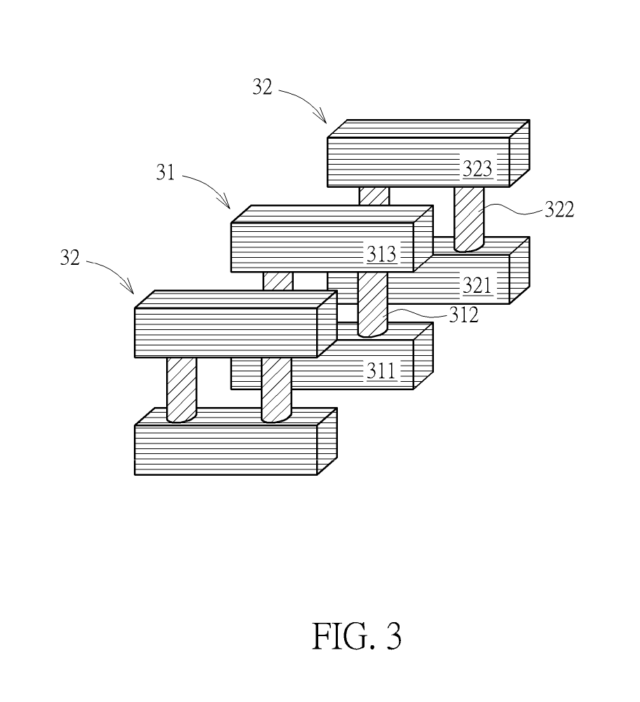

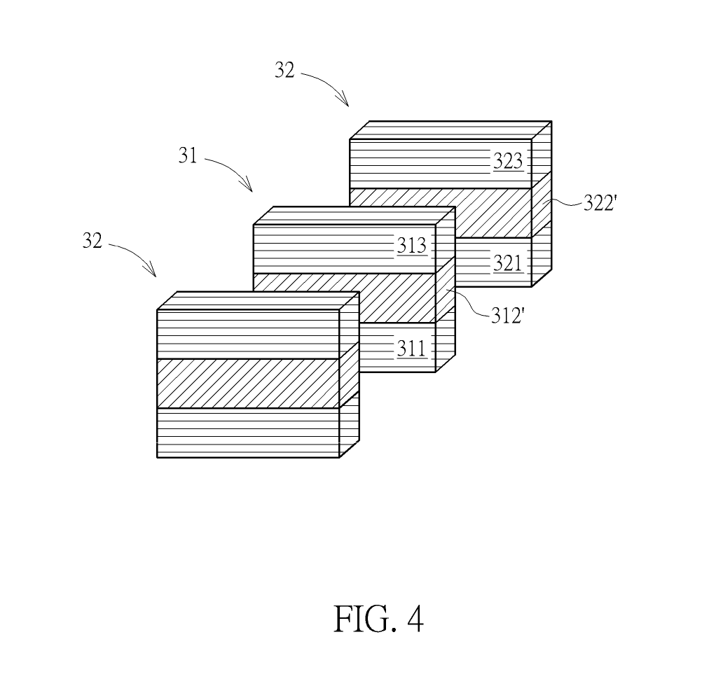

FIG. 3 and FIG. 4 are perspective diagrams showing the exemplary capacitor structure. According to the embodiment of the invention, the capacitor structure 30 is a vertical capacitor structure. The first electrode plate 31 and the second electrode plate 32 are both vertical to a main surface 100a of the semiconductor substrate 100. According to the embodiment of the invention, as shown in FIG. 3, the first electrode plate 31 of the capacitor structure 30 may be composed of a metal layer 311, a plurality of via plugs 312 and a metal layer 313, and the second electrode plate 32 may be composed of a metal layer 321, a plurality of via plugs 322 and a metal layer 323. The metal layer 311 and the metal layer 321 may be the first level metal (1M). The metal layer 313 and the metal layer 323 may be the second level metal (2M). A dielectric layer (not explicitly shown) may be formed between the first electrode plate 31 and the second electrode plate 32.

According to another embodiment of the invention, as shown in FIG. 4, the first electrode plate 31 of the capacitor structure 30 may be composed of a metal layer 311, a trench-type via plug 312′ and a metal layer 313, and the second electrode plate 32 may be composed of a metal layer 321, a trench-type via plug 322′ and a metal layer 323. Likewise, a dielectric layer (not explicitly shown) may be formed between the first electrode plate 31 and the second electrode plate 32. The aforesaid trench-type via plugs 312′/322′ are stripe shaped conductor, therefore the capacitance between the first electrode plate 31 and the second electrode plate 32 is increased.

By electrical coupling the floating diffusion node (FD) 12 to the source follower gate 24a and the first electrode plate 31 of the capacitor structure 30, and by electrical coupling the second electrode plate 32 of the capacitor structure 30 to a bias voltage (e.g., ground), charge handling capacitance (C_{FD}) of the floating diffusion node (FD) 12 of the CMOS image sensor is increased, thereby effectively improving the pixel dynamic range. In addition, the capacitor structure 30 of the present invention is a vertical capacitor structure, which may provide the maximum capacitance value in a limited area.

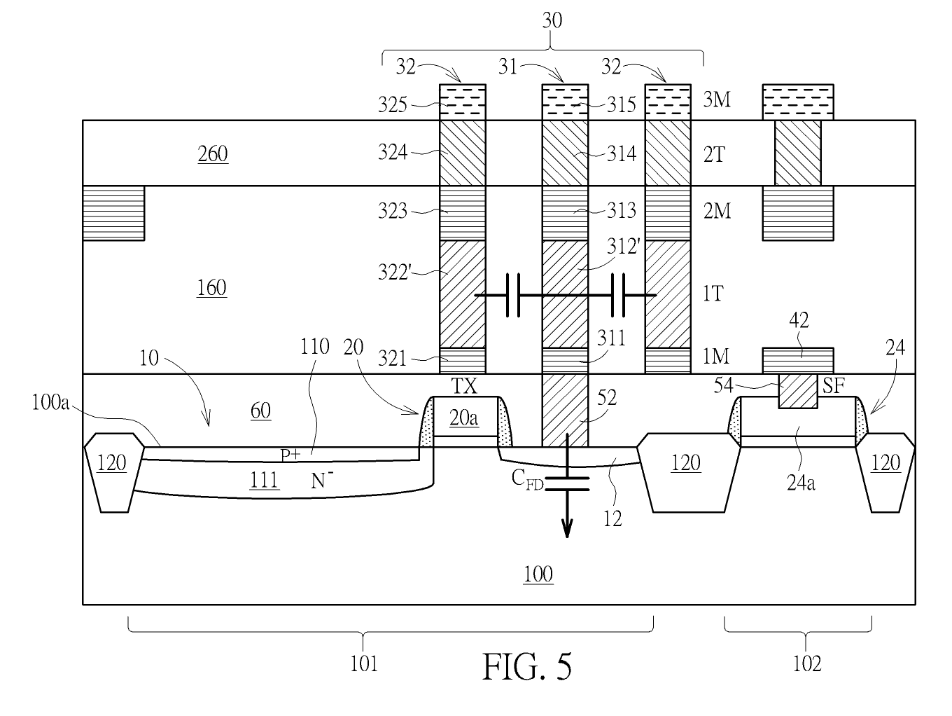

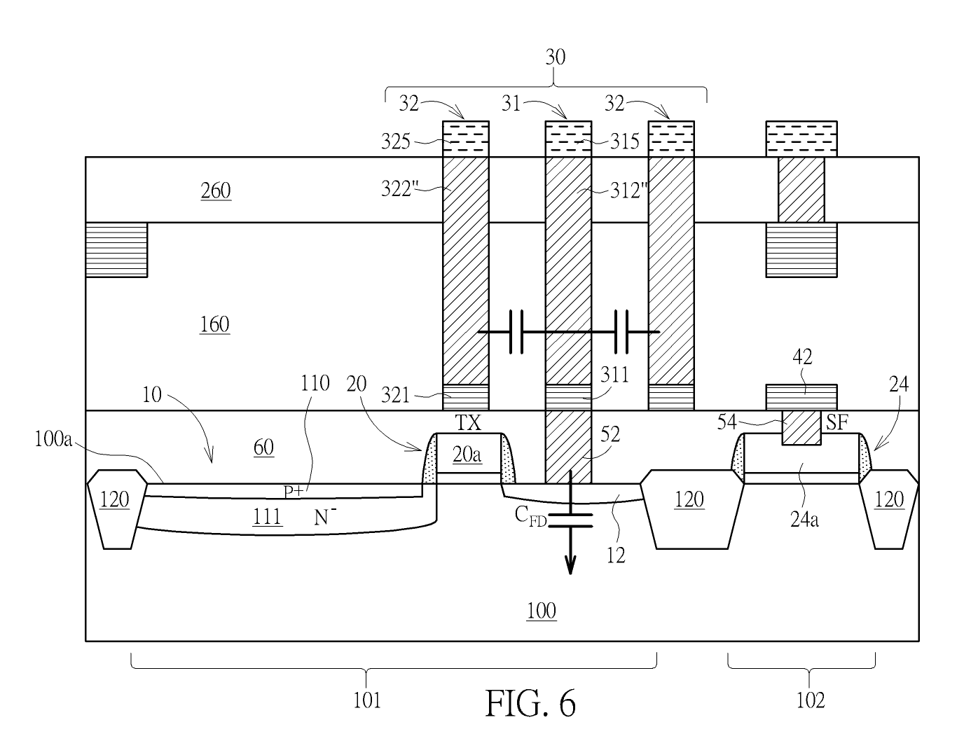

FIG. 5 and FIG. 6 are schematic cross-sectional diagrams showing CMOS image sensors according to other embodiments of the present invention. For the sake of simplicity, as in FIG. 2, only germane features are illustrated. As shown in FIG. 5, the capacitor structure 30 may be formed of the first-level metal (1M), the first-level via plug (1T), the second-level metal (2M), the second-level via plug (2T), and the third-level metal (3M). As shown in FIG. 6, the capacitor structure 30 may be formed of the first-level metal (1M), the second-level via plug (2T) and the third-level metal (3M).

The capacitor structure 30 may be formed in the dielectric layer 160 and 260, and the first-level metal (1M), the first-level via plug (1T), the second-level metal (2M), the second-level via plug (2T) and the third-level metal layer (3M) may comprise aluminum, copper, aluminum copper alloy, tungsten, titanium nitride, titanium, tantalum, tantalum nitride, but is not limited thereto.

In FIG. 5, the first electrode plate 31 of the capacitor structure 30 may be a stack comprising the metal layer 311, the trench-type via plug 312′, the metal layer 313, the trench-type via plug 314, and the metal layer 315. The second electrode plate 32 may be a stack comprising the metal layer 321, the trench-type via plug 322′, the metal layer 323, the trench-type via plug 324, and the metal layer 325. The metal layers 311/321 may be the first-level metal (1M), the trench-type via plugs 312′/322′ may be the first-level via plug (1T), the metal layers 313/323 may be the second-level metal (2M), the trench-type via plug 314/324 may be the second-level via plug (2T), the third metal layers 315/325 may be the third-level metal (3M).

In FIG. 6, the first electrode plate 31 of the capacitor structure 30 may be a stack comprising the metal layer 311, a trench-type via plug 312″, and the metal layer 315. The second electrode plate 32 may be a stack comprising the metal layer 321, the trench-type via plug 322″ and the metal layer 325. The trench-type via plug 312″ and 322″ can penetrate through the dielectric layers 160 and 260, which is inserted as a second-level via plug (2T) to directly connect the first metal layers 311/321 to the third metal layers 315/325.

Those skilled in the art will readily observe that numerous modifications and alterations of the device and method may be made while retaining the teachings of the invention. Accordingly, the above disclosure should be construed as limited only by the metes and bounds of the appended claims.

1. An image sensor, comprising:
a semiconductor substrate having a main surface;
a transfer transistor having a transfer gate disposed on the main surface of the semiconductor substrate;
a light-sensing structure disposed on one side of the transfer gate in the semiconductor substrate;
a floating diffusion node on the other side of the transfer gate in the semiconductor substrate;
a reset transistor serially connected to the transfer transistor through the floating diffusion node;
a source-follower transistor comprising a source-follower gate; and
a vertical capacitor structure having a first vertical electrode plate and a second vertical electrode plate, wherein the first vertical electrode plate is electrically coupled to the source-follower gate and the floating diffusion node.

2. The image sensor according to claim 1, wherein the source-follower gate is electrically coupled to the floating diffusion node through a first conductive plug, a first metal interconnection, and a second conductive plug.

3. The image sensor according to claim 2, wherein the first conductive plug and the second conductive plug are disposed in a same dielectric layer.

4. The image sensor according to claim 2, wherein the source-follower gate is electrically coupled to the first vertical electrode plate of the vertical capacitor structure through a second metal interconnection.

5. The image sensor according to claim 1, wherein the first vertical electrode plate and the second vertical electrode plate are interdigitated.

6. The image sensor according to claim 1, wherein the first vertical electrode plate and the second vertical electrode plate are disposed vertical to the main surface of the semiconductor substrate.

7. The image sensor according to claim 1 further comprising a readout transistor serially connected to the source-follower transistor through a commonly used doping region.

8. The image sensor according to claim 7, wherein the transfer transistor and the reset transistor are disposed on a first active region, and the source-follower transistor and the readout transistor are disposed on a second active region, wherein the first active region is isolated from the second active region by a shallow trench isolation (STI) structure.

9. The image sensor according to claim 1, wherein the light-sensing structure is a photodiode comprising a P⁺ surface doping region and an N⁻ doping region, which constitute a pinned photodiode in the semiconductor substrate.

10. The image sensor according to claim 1, wherein the first vertical electrode plate and the second vertical electrode plate are composed of a stack of a first metal layer, a trench-type via plug, and a second metal layer.

11. The image sensor according to claim 10 further comprising a dielectric layer disposed between the first vertical electrode plate and the second vertical electrode plate, and a capacitance is formed between the trench-type via plugs of the first vertical electrode plate and the second vertical electrode plate.

12. The image sensor according to claim 1, wherein the second vertical electrode plate is coupled to a bias voltage when in operation.

13. The image sensor according to claim 12, wherein the bias voltage is ground.
